(19) United States
(12) Patent Application Publication
(10) Pub. No.: US 2021/0328122 A1
(43) Pub. Date: Oct. 21, 2021

(54) FLEXIBLE THERMOELECTRIC DEVICE

(71) Applicant: Sumitomo Chemical Company Limited, Tokyo (JP)

(72) Inventors: Simon King, Godmanchester (GB); Wichita Koomar-Pokhot, Godmanchester (GB)

(73) Assignee: Sumitomo Chemical Company Limited, Tokyo (JP)

(21) Appl. No.: 17/264,989

(22) PCT Filed: Aug. 2, 2019
(86) PCT No.: PCT/GB2019/052171

§ 371 Date: Feb. 1, 2021

(30) Foreign Application Priority Data
Aug. 2, 2018 (GB) 1812585.6

(51) Int. Cl. H01L 35/32; H01L 35/08; H01L 35/16; H01L 35/34

(52) U.S. Cl. CPC H01L 35/32; H01L 35/34; H01L 35/16; H01L 35/08

(57) ABSTRACT

A flexible thermoelectric device that includes a plurality of pairs of semiconducting legs. The pair of semiconducting legs includes an n-type thermoelectric leg and a p-type thermoelectric leg. The pairs of thermoelectric legs are positioned between two substrates and are electrically connected in series in an alternating sequence between n-type and p-type legs. Both the n-type legs and the p-type legs are made from a binder containing semiconducting materials/particles that give the legs their n-type and p-type properties, respectively. The n-type and p-type legs are directly bonded with an electrode on one of the substrates by the binder. The flexible thermoelectric device nay be fabricated by contacting the electrode with the n-type and p-type legs and curing the binder.

### BACKGROUND

Embodiments of the present disclosure relate to a flexible thermoelectric device, for example a flexible thermoelectric generator (TEG).

A thermoelectric device can be used to generate electrical power or as a heating/cooling device. A thermoelectric device includes at least one thermoelectric element sandwiched between a pair of electrical contacts, where each of the pair of electrical contacts is disposed on a substrate. For purposes of this application, the terms “electrical contacts,” “contacts” and “electrodes” may be used interchangeably to describe the electrical contacts of the thermoelectric device.

Merely by way of example, the thermoelectric device may include a plurality of n-type thermoelectric elements and p-type thermoelectric elements. The thermoelectric elements may be spaced along a first direction and interposed between a pair of substrates. An array of contacts may be provided on each substrate. The contacts may be arranged to connect the thermoelectric elements in series. The thermoelectric elements may be arranged in a sequence of alternating n-type and p-type elements.

In use, a temperature difference may be applied across the thermoelectric device in a second direction that is different to and/or orthogonal to the first direction. The temperature difference is applied across a contact-thermoelectric element boundary. In response to the temperature difference, a voltage is generated by the thermoelectric elements. This voltage can be used to drive a current through the thermoelectric device. Alternatively, a current may be driven through the thermoelectric device to produce a temperature difference across the device which can be used to cool or heat a thermal load.

Thermal and electrical resistance between the contacts and the thermoelectric element affects the power efficiency of the thermoelectric device.

U.S. Pat. No. 7,999,172 (the “'172 patent”) describes a flexible thermoelectric device and a manufacturing method thereof. In the '172 patent, the flexible thermoelectric device comprises flexible substrates, offering a flexible property and tensile property to the thermoelectric device.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

Embodiments of the present disclosure provide a flexible thermoelectric device comprising an electrode and a pair of thermoelectric elements, an n-type thermoelectric element and a p-type thermoelectric element, where the pair of thermoelectric elements each comprise a binder and the pair of thermoelectric elements are bonded to the electrode by the binder. The pair of thermoelectric elements each comprise semiconducting particles that are distributed throughout the binder. In embodiments of the present disclosure, the binder and semiconducting particles form a printable material. In some embodiments, each of the pair of thermoelectric elements may be separately printed on further, individual and separate electrodes of the flexible thermoelectric device.

In some embodiments, the electrode and/or a substrate on which the electrode is disposed comprises a metallic foil. In some embodiments, the thermoelectric elements are bonded with the electrode of the flexible thermoelectric device so that at least 95% of the area of a given thermoelectric element is disposed on a given contact is in direct contact with that contact.

In embodiments of the present disclosure, the direct contact/direct bonding between the thermoelectric elements reduces thermal and electrical resistance between the thermoelectric elements and the electrode. Herein, “direct contact” is used to mean that the n-type and p-type thermoelectric elements are bonded or coupled to the electrode by the binder that forms the n-type and p-type thermoelectric elements, respectively. In embodiments of the present disclosure, the binder(s) provide an adhesive force between the thermoelectric elements and the electrode, providing for direct contact between the electrode and the pair of thermoelectric elements. A contact boundary is formed at a surface of each thermoelectric element in which the surface is in direct contact with the electrode.

In embodiments of the present disclosure, no cavities or intermediate elements are intentionally present at the contact boundary. Examples of intermediate elements include, but are not limited to, solder, anisotropically-conductive adhesive films and/or the like. In some embodiments, the flexible thermoelectric device does not contain additional bonding material and the binders bond or couple the thermoelectric elements to the electrode without the need for an additional bonding material between the thermoelectric elements and the contacts.

In some embodiments, each of the pair of thermoelectric elements forms a column like structure between pairs of electrodes of the flexible thermoelectric device, where both the n-type and the p-type pair of thermoelectric element columns are bonded with a common electrode at one end of the respective columns and with separate electrodes at the other end of the thermoelectric element columns. In embodiments of the present disclosure, the n-type thermoelectric element and the p-type thermoelectric element are electrically connected via the electrodes such that the n-type thermoelectric element and the p-type thermoelectric element are in electrical series. In some embodiments, the flexible thermoelectric device comprises a plurality of the pairs of thermoelectric elements, where the plurality of the pairs of thermoelectric elements are connected in series to provide, in use, for generation of an electrical current by the flexible thermoelectric device.

In some embodiments, the semiconducting particles comprise inorganic particles. In some embodiments of the present disclosure, the pair of thermoelectric elements are each directly bonded with the electrode, without the use of solder, a separate binder layer. In embodiments of the present disclosure, the electrode is not evaporated onto the pair of thermoelectric elements.

In some embodiments, the binder may comprise a polymer and/or an epoxy. In some embodiments, the n-type thermoelectric element may comprise an alloy of bismuth, and tellurium or selenium. In some embodiments, the p-type thermoelectric element may comprise an alloy of bismuth, tellurium and antimony.

In some embodiments of the present disclosure, a method for manufacturing a flexible thermoelectric device is provided. According to some embodiments of the present disclosure, an n-type thermoelectric element is coupled with a first electrode on a bottom substrate of the flexible thermoelectric device and a p-type thermoelectric element is coupled with a first electrode on a bottom substrate of the flexible thermoelectric device. In some embodiments, the n-type thermoelectric element and the p-type thermoelectric element are printed onto the first and the second electrodes of the bottom substrate,

In embodiments of the present disclosure, the n-type thermoelectric element and the p-type thermoelectric element extend between respective first and second electrodes of the bottom substrate and a first electrode of a top substrate, and both the n-type thermoelectric element and the p-type thermoelectric element are bonded with the first electrode of a top substrate. In some embodiments of the present disclosure, the bond between the n-type thermoelectric element and p-type thermoelectric elements and the first electrode of the top substrate is formed by curing the n-type thermoelectric element and p-type thermoelectric elements.

In some embodiments, the bond between the n-type thermoelectric element and p-type thermoelectric elements and the first electrode of the top substrate is produced by heating and then cooling the n-type and p-type thermoelectric elements, such that a binder(s) in the n-type thermoelectric element and the p-type thermoelectric element adhesively bond the n-type and p-type thermoelectric to the first electrode of the top substrate.

In some embodiments, the flexible thermoelectric device may be positioned in a thermally-conductive jig to apply pressure to the flexible thermoelectric device and the flexible thermoelectric device may then be heated and cooled to create an adhesive bond between the n-type thermoelectric element and p-type thermoelectric elements and the first electrode of the top substrate. In some embodiments, the flexible thermoelectric device may be heated to a temperature of about 150° to 250° for a time period of about 1 to 3 hours.

### BRIEF DESCRIPTION OF DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1A provides a schematic side view of a rigid thermoelectric generator.

FIG. 1B provides a schematic side view of a flexible thermoelectric generator using pressure to form contact between an electrode and a pair of thermoelectric legs and/or solder/an adhesive to bond the electrode and the pair of thermoelectric legs.

FIG. 1C provides a schematic side view of a flexible thermoelectric generator comprising an electrode that is evaporated onto a pair of thermoelectric legs.

FIG. 2A is a schematic side view of a flexible thermoelectric device, in accordance with some embodiments of the present disclosure.

FIG. 2B is a schematic side view of a flexible thermoelectric device with a rigid bottom substrate, in accordance with some embodiments of the present disclosure.

FIG. 2C is a schematic side view of a flexible thermoelectric device with a rigid top substrate, in accordance with some embodiments of the present disclosure.

FIG. 3 is a flow-type illustration of a method for manufacturing a flexible thermoelectric device, in accordance with some embodiments of the present disclosure.

FIG. 4 is a block diagram of an example of a thermoelectric system, in accordance with some embodiments of the present disclosure.

FIG. 5 is a scanning electron micrograph of a cross-section of a flexible thermoelectric device, in accordance with some embodiments of the present disclosure.

### DETAILED DESCRIPTION

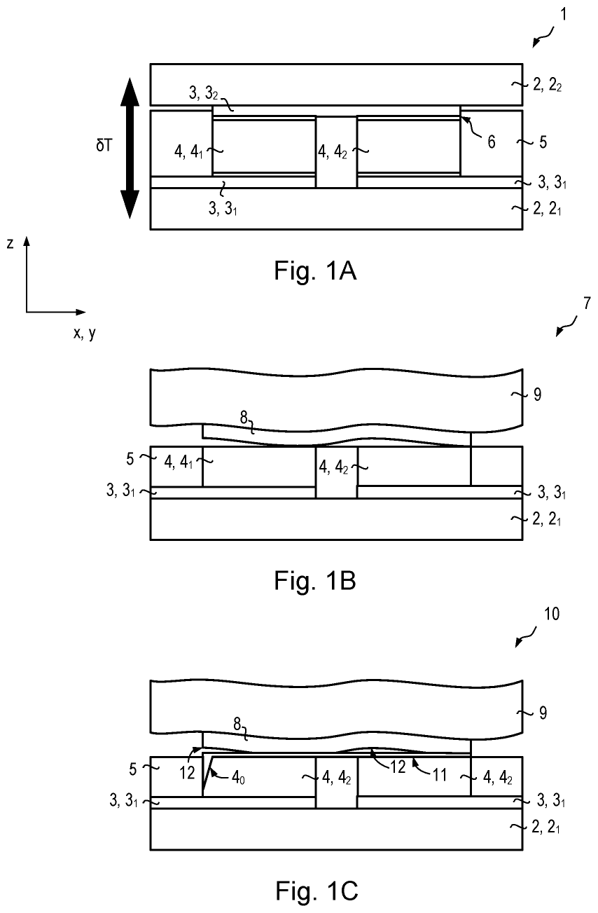

Flexible thermoelectric devices, such as thermoelectric generators may suffer from a number of issues with respect to the bonding/contact between the thermoelectric elements and the electrodes/electrical contacts of the thermoelectric device. These issues are detailed with reference to FIGS. 1A to 1C.

FIG. 1A provides a schematic side view of a rigid thermoelectric generator.

In FIG. 1A, a rigid thermoelectric generator 1 includes first and second substrates 2, 2₁, 2₂, two first contacts 3, 3₁ and a second contact 3, 3₂. The two first contacts 3₁ are co-planar, in other words, provided on the first substrate 2₁ and lie adjacent to each other. The substrates 2 are rigid. The contacts 3 are rigid.

The rigid thermoelectric generator 1 comprises n-type and p-type thermoelectric elements 4, 4₁, 4₂, an insulating structure 5, and solder 6. The n-type thermoelectric element 4₁ is provided on one first contact 3₁ and the p-type thermoelectric element 4₂ is provided on the other first contact 3₁. The second contact 3₂ is provided on the thermoelectric elements 4 such that the thermoelectric elements 4 are electrically-connected in series via the second contact 3₂. The second substrate 2₂ is provided on the second contact 3₂. The n-type thermoelectric element 4₁ and the p-type thermoelectric element 4₂, are sometimes referred to as “legs” or more particularly thermoelectric legs

The p-type and n-type thermoelectric elements 4₁, 4₂ are each electrically-connected to the contacts 3 via solder 6. The insulating structure 5 completely or partially fills the space surrounding the thermoelectric elements 4 to help ensure that the electrical connection between the thermoelectric elements 4 is only via the second contact 3₂. The insulating structure 5 may also completely or partially surround the contacts 3.

When a given temperature difference ST is applied across the layers of the rigid thermoelectric generator 1 (shown to lie along the z-axis), a voltage is induced across the thermoelectric elements 4. This voltage drives a current through the contacts 3 and thermoelectric elements 4 via the solder 6.

In thermoelectric device construction, most emphasis is directed towards the material used for the n-type and p-type thermoelectric elements, and the electronic performance/output of the materials when a temperature is applied across the n-type and p-type thermoelectric elements. However, Applicants have found that the solder 6 can introduce thermal and electrical resistance between the thermoelectric elements 4 and contacts 3, and this resistance can reduce the power efficiency of the rigid thermoelectric generator 1 for a given temperature difference ST.

FIG. 1B provides a schematic side view of a flexible thermoelectric generator using pressure to form contact between an electrode and a pair of thermoelectric legs and/or solder/an adhesive to bond the electrode and the pair of thermoelectric legs.

In FIG. 1B, a flexible thermoelectric generator 7 of has a similar structure to the rigid thermoelectric generator 1 of FIG. 1A. However, the flexible thermoelectric generator 7 comprises a second flexible contact 8 in place of the second contact 3₂. The second flexible contact 8 is provided on a second flexible substrate 9. The second flexible contact 8 may be held in place by pressure alone, rather than by solder 6.

As with the rigid thermoelectric generator illustrated in FIG. 1A, Applicants have found that the flexible thermoelectric generator 7 may have detrimental performance issues associated with the coupling of the second flexible contact 8 with the n-type thermoelectric element 4₁ and the p-type thermoelectric element 4₂. For example, where the second flexible contact 8 is held in contact with the second flexible contact 8 by pressure, this can introduce thermal and electrical resistance between the thermoelectric elements 4 and second flexible contact 8, and can result in a reduced power efficiency of the flexible thermoelectric generator 7 for a given temperature difference ST applied across the flexible thermoelectric generator 7. Alternatively, where the second flexible contact 8 is held in contact with the second flexible contact 8 by a solder paste (not shown), this can introduce thermal and electrical resistance between the thermoelectric elements 4 and the second flexible contact 8.

The first contacts 3₁ may be replaced by first flexible contacts (not shown). A first flexible substrate (not shown) is provided on the first flexible contacts. The first flexible contacts may be held in place by pressure alone or by a solder paste (not shown). The presence of the first flexible contact introduces similar drawbacks as hereinbefore described in relation to the second flexible contact 8.

FIG. 1C provides a schematic side view of a flexible thermoelectric generator comprising an electrode that is evaporated onto a pair of thermoelectric legs.

In FIG. 1C, a flexible thermoelectric generator 10 has a similar structure to the flexible thermoelectric generator 7 illustrated in FIG. 1B. The flexible thermoelectric generator 10 comprises a contact layer 11 that is evaporated onto the thermoelectric elements 4. In some embodiments, a second flexible contact 8 is provided between the contact layer 11 and the second flexible substrate 9. In other embodiments, the contact layer 11 acts as the contact and is sandwiched between the second flexible substrate 9 and the thermoelectric elements 4.

Applicants have found that directly evaporating an electrical contact layer onto the thermoelectric elements 4 can have adverse effects on the operation of the thermoelectric device. For example, if the thermoelectric elements 4 have been printed unevenly onto the first contacts 3₁, providing the second layer 11 on the uneven surface may cause electrical shorting. FIG. 1C shows a region of the thermoelectric element 4₁ with an uneven surface 4₀. Furthermore, since the flexible thermoelectric generator 10 may be flexed in operation this unevenness may be amplified, increased or the like. The presence of gaps 12 between the contact layer 11 and the second flexible contact 8 or the thermoelectric elements 4 can cause electrical shorting and introduce thermal and electrical resistance between the thermoelectric elements 4 and second flexible contact 8, resulting in reduced power efficiency.

As with the flexible thermoelectric generator 7, illustrated in FIG. 1B, the first contact 3₁ may be replaced by a first flexible contact (not shown). The first flexible contact is provided on a first flexible substrate (not shown). A first contact layer (not shown) is applied to the thermoelectric elements 4 prior to the first flexible contact being applied so that the first flexible contact is provided between the first contact layer and the first flexible substrate. The first contact layer is similar to the contact layer 11 and is evaporated on the thermoelectric elements 4 prior to the first flexible contact being applied. The presence of the first contact layer introduces similar drawbacks as hereinbefore described with respect to the contact layer 11.

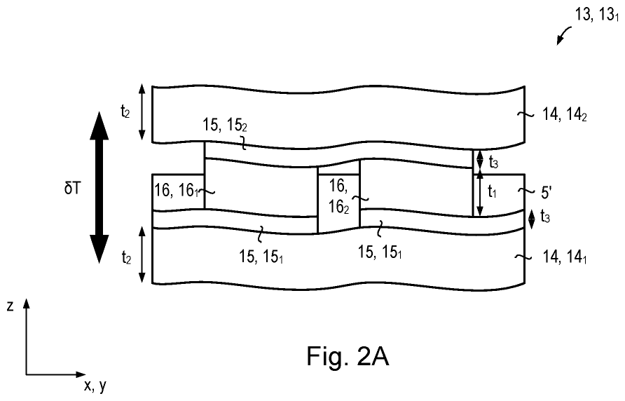

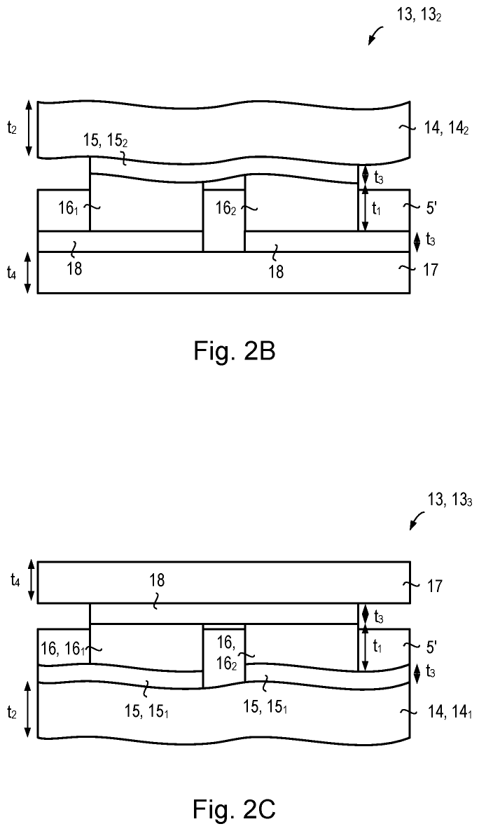

FIG. 2A provides a schematic side view of a flexible thermoelectric device, in accordance with some embodiments of the present disclosure.

In FIG. 2A, a first flexible thermoelectric device 13, 13₁ comprises at least one thermoelectric couple. In FIG. 2A, the first flexible thermoelectric device 13₁ comprises one thermoelectric couple, but in general the flexible thermoelectric device 13 may comprises a plurality of the thermoelectric couples integrated together to form the flexible thermoelectric device 13.

In some embodiments of the present disclosure, the thermoelectric couple comprises a first substrate 14, 14₁, two first contacts 15, 15₁, an n-type thermoelectric element 16, 16₁, a p-type thermoelectric element 16, 16₂, a second contact 15, 15₂, and a second substrate 14₂. In some embodiments, the thermoelectric couple may also comprise an insulating structure 5′ which completely or partially fills the space surrounding the thermoelectric elements 16. In embodiments of the present disclosure, the substrates 14 and contacts 15 are flexible.

In some embodiments, a first face of each first contact 15₁ is provided on the first substrate 14₁. The n-type thermoelectric element 16₁ is provided on a second, different face of one first contact 15₁. The p-type thermoelectric element 16₂ is provided on the second face of the other first contact 15₁. A first face of the second contact 15₂ is provided on the second substrate 142. A second, different face of the second contact 15₂ is provided on the n-type and p-type thermoelectric elements 16₁, 16₂. The n-type and p-type thermoelectric elements 16₁, 16₂ are electrically-connected via the second contact 15₂.

In some embodiments, the contacts 15 are deposited on, bonded and/or the like to the substrates 14. In some embodiments, there are no intervening layers between the contacts 15 and the substrates 14.

The first flexible thermoelectric device 13₁ may comprise a plurality of thermoelectric couples electrically-connected via the first and second contacts 15₁, 15₂. In some embodiments, the thermoelectric couples are arranged so that the n-type and p-type thermoelectric elements 16₁, 16₂ are electrically-connected in series. In some embodiments, the thermoelectric elements 16 are connected in an alternating sequence between n-type and p-type thermoelectric elements 16₁, 16₂. In embodiments of the present disclosure, a current is generated through the first flexible thermoelectric device 13₁ upon application of a temperature difference ST across the first flexible thermoelectric device 13₁.

In some embodiments, each n-type thermoelectric element 16₁ and each p-type thermoelectric element 16₂ may be directly provided on the contacts 15. The thermoelectric elements 16 remain in direct contact with the contacts 15 even as the contacts 15 curve or flex with the substrates 14. In some embodiments, the direct contact reduces the thermal and electrical resistance (“contact resistance”) between the thermoelectric elements 16 and the contacts 15. Thus, power efficiency of the first flexible thermoelectric device 13₁ can be improved, for example, compared with the flexible thermoelectric generators illustrated in FIG. 1B and FIG. 1C for a given temperature difference δT.

In some embodiments, each n-type thermoelectric element 16₁ is formed from a first material comprising a dispersion of first semiconducting particles in a first binder. In some embodiments, the first semiconducting particles may comprise or consist of an alloy of bismuth (Bi), and tellurium (Te) or selenium (Se), for example, Bi₂Te₃, and Bi₂Se₃, and/or optionally an additional first dopant. Examples of first dopants include selenium (Se), bismuth (Bi), sulfur (S), iodine (I) and/or the like. In some embodiments, the concentration of the first dopant may be between 1% and 10%.

In some embodiments, each p-type thermoelectric element 16₂ may be formed from a second material comprising a dispersion of second semiconducting particles in a second binder. In some embodiments, the second semiconducting particles may comprise or consist of an alloy of bismuth (Bi), tellurium (Te), and antimony (Sb), for example Bi_{1.5}Sb_{0.5}Te₃, and/or an additional second dopant. In some embodiments, the second semiconducting particles may comprise or consist of an alloy of lead (Pb) and tellurium (Te), an alloy of tin (Sn) and selenium (Se), or an alloy of silicon (Si) and germanium (Ge), and/or optionally an additional second dopant. Examples of second dopants include tellurium (Te), selenium (Se), sulfur (S), arsenic (As), antimony (Sb), phosphorus (P), bismuth (Bi) and the halogens. The concentration of second dopant may be between 1% and 10%.

In some embodiments, the first and second binders may comprise first and second polymers, first and second epoxy resins and/or the like. In some embodiments, each thermoelectric element 16 may have a thickness, t₁, of between 40 and 200 μm when the first flexible thermoelectric device 13₁ is not being flexed. For purposes of this description, the thickness is taken to be in the direction in which the materials are layered or stacked in the first flexible thermoelectric device 13₁ (here shown to lie along the z-axis).

In some embodiments, the first and second substrates 14₁, 14₂ may comprise flexible ceramic, plastic film, metal foil and/or the like. The first and second substrates 14₁, 14₂ may comprise a combination of materials, for example a metal foil coated on one surface with an electrically-insulating layer, the electrically-insulating layer being thinner than the metal foil. In some embodiments, the contacts 15 may be disposed directly on the electrically insulating layer. In some embodiments, there may be no intervening layers between the contacts 15 and the electrically-insulating layer. In some embodiments, the substrates 14 may have a thickness, t₂, between 30 and 60 μm. The first and second substrates 14₁, 14₂ may be made of the same material or different materials.

The first and second contacts 15₁, 15₂ may comprise a single conductive layer or a stack of multiple conductive layers. The or each conductive layer may be formed of a single conductive material or two or more materials, for example, in the form of an alloy. Examples of conductive materials include metals, such as copper or gold, conductive metal oxides and/or the like. The first and second contacts 15₁, 15₂ may be made of the same material or different materials. In some embodiments, the contacts 15 may have thicknesses, t₃, between 1 and 5 μm. In some embodiments, the insulating structure 5′ may take the form of a photoresist.

In some embodiments of the present disclosure, the first flexible thermoelectric device 13₁ may have a bend radius of about 30 mm or less or about 20 mm or less. In some embodiments, the bend radius may be at least 5 mm or at least 10 mm.

FIG. 2B is a schematic side view of a flexible thermoelectric device with a rigid bottom substrate, in accordance with some embodiments of the present disclosure.

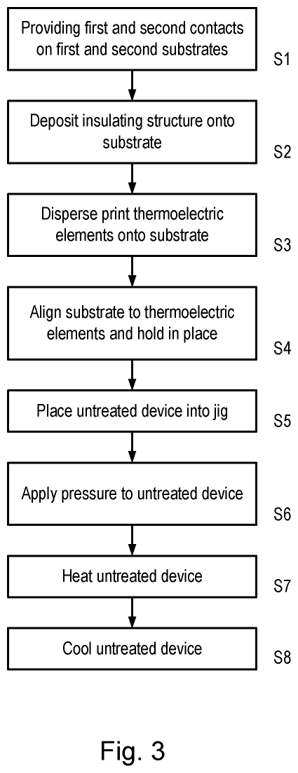

In FIG. 2B, a second flexible thermoelectric device 132 is depicted that is similar to the first flexible thermoelectric device 13₁ illustrated in FIG. 3a. However, the second flexible thermoelectric device 13₂ includes a rigid substrate 17.

In some embodiments, first contacts 15₁ may be provided on the rigid substrate 17. Alternatively, rigid contacts 18 may be provided on the rigid substrate 17. The rigid contacts 18 are similar to the first contacts 15₁, but the rigid contacts 18 are not flexible.

The rigid substrate 17 may comprise rigid ceramic. The rigid substrate 17 may comprise a combination of layered materials, for example adhesive on glass. The rigid substrate 17 may have a thickness, t₄, of between 30 and 100 μm.

FIG. 2C is a schematic side view of a flexible thermoelectric device with a rigid top substrate, in accordance with some embodiments of the present disclosure.

In FIG. 2C, a third flexible thermoelectric device 13₃ is depicted that is similar to the first flexible thermoelectric device 13₁ of FIG. 2a. However, the third flexible thermoelectric device 13₃ includes the rigid substrate 17 in place of the second substrate 14₂ (FIG. 2a).

The first contacts 15₁ may be provided on the rigid substrate 17. Alternatively, the rigid contacts 18 may be provided on the rigid substrate 17.

In accordance with some embodiments of the present disclosure, power efficiency of the second and third flexible thermoelectric devices 13₂, 13₃ can be improved, for example, compared with the first and second flexible thermoelectric generators 7, 10 illustrated in FIGS. 1B and 1C for a given temperature difference δT, by bonding the contact and the n-type and p-type thermoelectric elements in the manner described with respect to the first flexible thermoelectric device 13₁ illustrated in FIG. 2A.

### Manufacture of Flexible Thermoelectric Device

FIG. 3 is a flow-type illustration of a method for manufacturing a flexible thermoelectric device, in accordance with some embodiments of the present disclosure.

In some embodiments, two first contacts 15₁ are deposited on the first substrate 14₁ and one second contact 15₂ is deposited on the second substrate 14₂ (step S1). In some embodiments, the contacts 15 may be formed by sputtering.

In some embodiments, the insulating structure 5′ is provided on the first substrate 14₁ so as to form wells into which the thermoelectric elements 16₂, 16₂ are provided (step S2). The insulating structure 5′ may be provided by deposition and photolithography, or by a printing process such as screen printing.

In some embodiments, the thermoelectric elements 16₁, 16₂ are provided on the first contacts 15₁ by dispenser printing (step S3).

In some embodiments, the second substrate 14₂ is aligned on top of the thermoelectric elements 16₁, 16₂ such that the second contact 15₂ is in contact with the thermoelectric elements 16₁, 16₂. In some embodiments, the second substrate 14₂ is held in place, preferably by using adhesive tape (not shown) (step S4). After completing step S4, an untreated device is formed. Alternatively, the insulating structure 5′ may be deposited on the second substrate 14₂ in place of the first substrate 14₁, and the first substrate 14₁ aligned on top of the thermoelectric elements 16 after the thermoelectric elements 16 have been deposited on the second contact 15₂. Herein, “untreated device” refers to the flexible thermoelectric device 13 prior to the thermoelectric elements 16 directly bonding to the contacts 15.

In some embodiments, when the untreated device is treated, the contacts 15 are bonded to the n-type thermoelectric element 16₁ by the first binder and the contacts 15 are bonded to the p-type thermoelectric element 16₂ by the second binder. The untreated device is placed into a jig (not shown) made from conductive material. In some embodiments, the conductive material comprises aluminium. The untreated device may be disposed in the jig between two sheets of silicon (step S5).

The jig applies pressure to the untreated device, the pressure being applied normally to an outer face of the first and second substrates 14₁, 14₂ (step S6). Thus, the pressure is applied to the first substrate in a first direction and to the second substrate in a second, different direction. The first direction is normal to the first face of the first contact, and the second direction is normal to the first face of the second contact.

In some embodiments of the present disclosure, whilst pressure is applied, the untreated device is heated (“cured”), for example by an oven or hot plate (step S₇). In some embodiments, the untreated device may be heated at between about 150° and 250° for between about 1 and 3 hours.

After cooling (step S8), which in some embodiments may comprise cooling to room temperature, a bond between the contact and the n-type and p-type thermoelectric elements is cured providing direct bonding between the contact and the n-type and p-type thermoelectric elements.

The second flexible thermoelectric device 13₂ (FIG. 2b) and the third thermoelectric device 13₃ (FIG. 2c) may be produced using a similar method of manufacture to the first flexible thermoelectric device 13₁.

In some embodiments of the present disclosure, directly depositing the contacts 15 onto the substrates 14 reduces or even prevent the contacts 15 conforming to any high aspect ratio defects or uneven surfaces, (such as the uneven surface 40 shown FIG. 1c) of the thermoelectric elements 16 when the thermoelectric elements 16 are provided on the contacts 15.

### Thermoelectric System

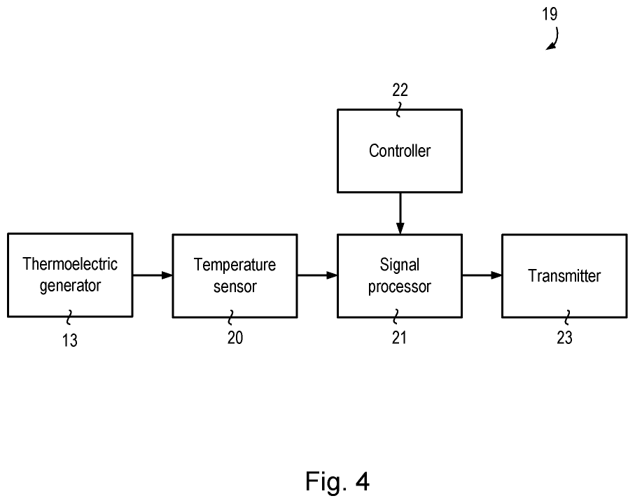

Referring to FIG. 4, an example thermoelectric system (“the system”) 19 is shown. The system 19 may be used to measure a surface temperature of a remote component (not shown) and transmit temperature data to a remote receiver (not shown).

The system 19 comprises the flexible thermoelectric device 13, a temperature sensor 20, a signal processor unit 21, a controller unit 22, and a transmitter unit 23. The flexible thermoelectric device 13 is provided on a surface of the remote component. The component may be a pipe or a moving mechanical element, for example an actuator. The flexible thermoelectric device 13 includes at least one substrate (not shown) that can curve to maintain surface contact with the component to reduce thermal resistance at the contact surface.

The flexible thermoelectric device 13 converts the waste heat produced by the component into useful energy to power the temperature sensor. The signal processor 21 receives at least one signal from the temperature sensor 20. The signal indicates the temperature of the component.

In response to receiving control signals from the controller 22, the signal processor 21 processes the signal. The transmitter 23 receives the processed signal and transmits the processed signal to the external receiver (not shown).

### Comparison of Performance

Referring to FIG. 2A, the performance of the first flexible thermoelectric device 13₁ is now compared to a similar thermoelectric device, without the direct bonding between the contact and the n-type and p-type thermoelectric elements in accordance with some embodiments of the present disclosure.

Decreasing the thermal and electrical resistance between the contacts 15 and thermoelectric elements 16 increases the power efficiency of the flexible thermoelectric device 13. Therefore, the performance of the flexible thermoelectric device 13 is indicated by its power output.

The similar thermoelectric device has the same structure as the first flexible thermoelectric device 13₁ and comprises the same materials. However, during manufacture, the similar thermoelectric device is cured before the contacts are provided on the thermoelectric elements.

Table 1 below compares the performance of the first flexible thermoelectric device 13₁ (“original process”) to the similar thermoelectric device (“cure after assembly”).

TABLE 1

| | Module | Module Power |
|---|---|---|
| | Resistance/Ω | Output/μW |
| Original process (cure | 55.0 | 4.4 |
| before assembly) | | |
| Cure after assembly | 4.7 | 23.9 |

Thus, the first flexible thermoelectric device 13₁ has greater power efficiency compared to the similar thermoelectric device.

### Scanning Electron Micrograph Image

As hereinbefore described, the thermoelectric elements 16 (FIG. 2A) are disposed on the contacts so that at least 95% of the area of a given thermoelectric element disposed on a given contact is in direct contact with that contact.

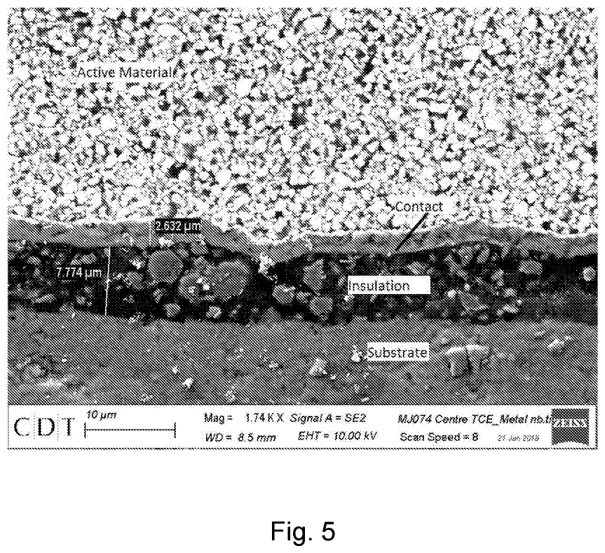

Referring to FIG. 5, a scanning electron micrograph (SEM) image of a cross-section of the flexible thermoelectric device 13 (FIG. 3a) is shown. FIG. 5 illustrates at least 95% area contact between the thermoelectric element (“active material”) and the contacts. The embodiment of the flexible thermoelectric device 13 (FIG. 3a) shown in FIG. 5 comprises a substrate formed from a metal foil (“substrate”) coated on one surface with an electrically-insulating layer (“insulation”).

The description above provides preferred exemplary embodiment(s) only, and is not intended to limit the scope, applicability or configuration of the invention. Rather, the ensuing description of the preferred exemplary embodiment(s) will provide those skilled in the art with an enabling description for implementing a preferred exemplary embodiment of the invention, it being understood that various changes may be made in the function and arrangement of elements, including combinations of features from different embodiments, without departing from the scope of the invention.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

1. A flexible thermoelectric device, comprising:
an upper substrate comprising a first upper electrode;
a lower substrate comprising a first lower electrode and a second lower electrode;
an n-type thermoelectric element having a column-like structure with a first end and a second end and comprising semiconducting particles distributed in a first binding material comprising a first epoxy resin, wherein the n-type thermoelectric element is disposed between the upper and the lower substrates and the second end of the n-type thermoelectric element is coupled with the first lower electrode; and
a p-type thermoelectric element having a column-like structure with a first end and a second end and comprising semiconducting particles distributed in a second binding material comprising a second epoxy resin, wherein the p-type thermoelectric element is disposed between the upper and the lower substrates and the second end of the p-type thermoelectric element is coupled with the second lower electrode; wherein: the first end of the n-type thermoelectric element and the first end of the p-type thermoelectric element are adhesively bonded by the binder material to the first upper electrode.

2. The flexible thermoelectric device according to claim 1, wherein the semiconducting particles are distributed throughout the column-like structures of the n-type and the p-type thermoelectric elements.

3. The flexible thermoelectric device according to claim 1, wherein at least one of the upper substrate and the first upper electrode comprise a metallic foil.

4. The flexible thermoelectric device according to claim 1, wherein the n-type thermoelectric element and the p-type thermoelectric element both comprise a printable material.

5. The flexible thermoelectric device according to claim 1, wherein the semiconducting particles of the n-type thermoelectric element and the p-type thermoelectric element comprise inorganic particles.

6. The flexible thermoelectric device according to claim 1, wherein the flexible thermoelectric device does not comprise additional bonding material between the n-type thermoelectric element or the p-type thermoelectric element and the first upper electrode.

7. The flexible thermoelectric device according to claim 1, wherein the adhesive bonds do not comprise solder.

8. The flexible thermoelectric device according to claim 1, wherein the first and second binders comprise first and second polymers.

9. (canceled)

10. The flexible thermoelectric device according to claim 1, wherein the semiconducting particles of the n-type thermoelectric element comprise an alloy of bismuth, and tellurium or selenium.

11. The flexible thermoelectric device according to claim 10, wherein the semiconducting particles of the n-type thermoelectric element comprise Bi₂Te₃, or Bi₂Se₃.

12. The flexible thermoelectric device according to claim 10, wherein the semiconducting particles of the n-type thermoelectric element comprise Bi₂Te₃ doped with Se.

13. The flexible thermoelectric device according to claim 1, wherein the semiconducting particles of the p-type thermoelectric element comprise an alloy of bismuth, tellurium and antimony.

14. The flexible thermoelectric device according to claim 13, wherein the semiconducting particles of the p-type thermoelectric element comprise Bi_{1.5}Sb_{0.5}Te₃.

15. The flexible thermoelectric device according to claim 1, wherein the n-type thermoelectric element and the p-type thermoelectric element are electrically connected in series.

16. A method for producing a flexible thermoelectric device, comprising:
providing a bottom substrate comprising a first and a second electrical contact;
disposing an n-type thermoelectric element on the first electrical contact, wherein the n-type thermoelectric element is formed from a first material comprising a dispersion of first semiconducting particles in a first binder;
disposing a p-type thermoelectric element on the second electrical contact, wherein the p-type thermoelectric element is formed from a second material comprising a dispersion of second semiconducting particles in a second binder;
providing a top substrate comprising a top electrical contact;
contacting the top electrical contact with the n-type and the p-type thermoelectric elements; and
using the first and the second binders to bond to the n-type and p-type thermoelectric elements to the top electrical contact.

17. The method according to claim 16, wherein using the first and the second binders to bond to the n-type and p-type thermoelectric elements to the top electrical contact comprises curing the first and second binders.

18. The method according to claim 17, wherein curing the first the second binders comprises heating and then cooling the n-type and p-type thermoelectric elements.

19. The method according to claim 16, wherein disposing the n-type thermoelectric element on the first electrical contact comprises printing the n-type thermoelectric element onto the first contact.

20. (canceled)

21. The method according to claim 16, further comprising:
placing the flexible thermoelectric device into a thermally-conductive jig;
using the jig to apply pressure to the flexible thermoelectric device, wherein the pressure is applied between the top substrate and the bottom substrate;
heating the flexible thermoelectric device; and
cooling the flexible thermoelectric device.

22-23. (canceled)

24. A flexible thermoelectric device manufactured by the method according to claim 16.
